(19) United States
(12) Patent Application Publication
(10) Pub. No.: US 2026/0156737 A1
(43) Pub. Date: Jun. 4, 2026

(54) RADIOFREQUENCY (RF) CIRCUITS WITH MITAGATED SURFACE ROUGHNESS AND CORRESPONDING SYSTEMS AND METHODS

(71) Applicant: Mellanox Technologies, Ltd., Yokneam (IL)

(72) Inventors: Ella SANDERS, HaSolelim (IL); Rotem Glick CARMI, Kiryat Motzkin (IL); Isabelle CESTIER, Haifa (IL); Ziv ABELSON, Even Yehuda (IL); Elad MENTOVICH, Tel Aviv (IL); Timothy DE KEULENAER, Ghent (BE); Marijn VERBEKE, Gent (BE)

(21) Appl. No.: 19/050,471

(22) Filed: Feb. 11, 2025

Related U.S. Application Data
(60) Provisional application No. 63/727,740, filed on Dec. 4, 2024.

(51) Int. Cl. H05K 1/02; H05K 1/18; H05K 3/10

(52) U.S. Cl. CPC H05K 1/0216; H05K 1/0237; H05K 1/181; H05K 3/10

(57) ABSTRACT

An electrical component includes at least one conducting trace configured for conducting radiofrequency (RF) signals. The at least one conducting trace has a broadband conductive material applied onto one or more specific locations along the at least one conducting trace. In certain embodiments, the one or more specific locations are locations detected or anticipated to have surface roughness. In certain embodiments, the presence of the broadband conductive material improves the signal integrity of RF signals conducted along the conducting trace (compared to if the broadband conductive material was not present). Certain embodiments provide methods for fabricating such electrical components.

### CROSS-REFERENCE TO RELATED APPLICATION(S)

This application claims priority to U.S. Application No. 63/727,740, filed Dec. 4, 2024, the content of which is incorporated herein by reference in its entirety.

### BACKGROUND

The present disclosure relates to the field of signal transmission, and more particularly, to improving signal integrity (SI) in high-speed RF (radiofrequency) circuits.

Datacenters and other networking systems may include connections between switch systems, servers, racks, and devices in order to provide for signal transmission between one or more of these elements. These connections may be made using cables, transceivers, and connector assemblies that utilize optical, copper, and/or similar transmission mediums. Due to the large number of connections in these environments, copper cabling may be used for connections over short distances in order to minimize cost. Demands on RF systems are on the rise. Modern systems are called upon to support higher data rates over tightening bandwidth. Furthermore, the proliferation of RF devices has led to demand for support across multiple frequency bands. New bands of the frequency spectrum are continually released to meet capacity demands. Each of these factors has led to increased power consumption in RF transmitters, and specifically, increased power demands and decreased efficiency in power amplifiers. As demands have grown, so too has RF technology. For example, the evolution of 3G, 4G and long term evolution (LTE) communication networks have led to significant increases in RF signal dynamic range and increased peak power to accommodate higher data rates and more complex modulation schemes. The availability of varieties of channel coding and modulation techniques, the demand for broader channel bandwidths, and high PAPR modulation schemes all press their demands on power availability and efficiency. Reflections and scattering of RF signals within the signal conduit are common issues that deteriorate SI in RF circuits. Previous techniques include impedance matching of materials and structures, and suitable design of the transmission lines. RF circuits are typically produced on printed circuit board (PCB) substrates, having features with relatively large sizes (tens or hundreds of microns, larger than 1 μm) which are processed material application by methods such as spray coating, wet etching, etc., rather than more complex processes applied to much smaller features (few to tens or hundreds of nanometers, smaller than 1 μm) in the VLSI (very large-scale integration) industry.

### GENERAL DESCRIPTION

Surface roughness of a conductive medium of high-speed conducting lines can cause reflections and scattering of the RF (radio frequency) signal in the high-speed conducting lines. These reflections and scattering can affect the signal integrity in high-speed RF circuits. The RF signal may be a modulated RF signal (frequency in a range of 3 kHz to 300 GHz or 100 MHz to 300 GHz for some applications) for communications applications. Even when the surface of the conductive medium has a high root mean square (RMS) rate, specific areas such as grain boundaries or surface defects can create a local roughness that may cause scattering and reflection when encountered by a surface plasmon polariton and compromise the signal integrity. Previous techniques as described above, do not address issues related to surface plasmon polaritons (SPP) s and their presence on the surface of the metal, in combination with their interaction with surface defects. The present disclosure provides a technique selectively applying a functional coating aimed at improving signal integrity over specific areas prone to SI losses due to surface waves on the PCB/component.

A PCB is used to electrically connect electronic components using conductive pathways, or traces, etched from metal sheets. In many electronic systems, one or more semiconductor devices or very large-scale integrated circuit (VLSI) components is coupled to a host system PCB. Such VLSI components may include, for example, central processing unit (CPU) devices, graphics processing unit (GPU) devices, data processing unit (DPU) devices, quantum processing unit (QPU), and/or physics processing unit (PPU). The PCB may hold at least one processing circuitry. The processing circuitry may comprise hardware, such as an application specific integrated circuit (ASIC). The processing circuitry may comprise an ASIC and/or may be capable of performing as a CPU, a GPU, a network interface controller (NIC), a DPU, or any other computing device in which with data is received and/or transmitted. Other non-limiting examples of the processing circuitry include an Integrated Circuit (IC) chip, a CPU, a GPU, a microprocessor, a Field Programmable Gate Array (FPGA), a collection of logic gates or transistors, resistors, capacitors, inductors, diodes, or the like. PCBs enable the integration of multiple electronic components, such as separately packaged ICs, capacitors, resistors, voltage regulators, and the like, into a single compact assembly. Such assemblies oftentimes are referred to as printed circuit board assemblies (PCBAs) and are used in a wide range of communication and computing implementations, including, without limitation, mobile phones, laptop computers, desktop computers, and server machines.

In high-performance implementations, such as graphics cards and server machines, certain electronic components of a PCBA can generate significant heat during operation. To prevent over-heating, the generated heat has to be transferred away from the PCBA. Accordingly, in practice, many high-performance PCBAs include, or are coupled, to a heat sink, cold plate, or other thermal solution that greatly increases the amount of heat transfer away from the PCBA. Typically, the thermal solution is a heat transfer apparatus that is mounted on a PCBA such that a cooling surface of the thermal solution is coupled to a heat-generating component of the PBCA, such as a high-power IC. In such a configuration, the thermal solution transfers heat directly away from the heat-generating component. The GPU/CPU may include or otherwise be in communication with processing circuitry that is configurable to perform actions in accordance with one or more example embodiments disclosed herein. In this regard, the processing circuitry may be configured to perform and/or control performance of one or more functionalities of the GPU/CPU in accordance with various example embodiments, and thus may provide means for performing functionalities of the GPU/CPU in accordance with various example embodiments. The processing circuitry may be configured to perform data processing, application execution and/or other processing and management services according to one or more example embodiments. In some embodiments, the GPU/CPU or a portion(s) or component(s) thereof, such as the processing circuitry, may be embodied as or comprise a semiconductor device or chip or chip set. In other words, the GPU/CPU or the processing circuitry may comprise one or more physical packages (e.g., chips) including materials, components and/or wires on a structural assembly (e.g., a baseboard). The structural assembly may provide physical strength, conservation of size, and/or limitation of electrical interaction for component circuitry included thereon. The GPU/CPU or the processing circuitry may therefore, in some cases, be configured to implement an embodiment of the disclosure on a single chip or as a single “system on a chip.” As such, in some cases, a chip or chipset may constitute means for performing one or more operations for providing the functionalities described herein. It should be appreciated that any appropriate type of electrical or optical component or collection of electrical or optical components may be suitable for inclusion in the processing circuitry. Numerous example embodiments will be described below in which a semiconductor IC package is mounted within a through hole of a PCB. The IC package may be assembled by connecting electrical components to the substrate, attaching at least one pedestal to the substrate, and reversibly securing a lid to the at least one pedestal. Embodiment of the IC package can further include voltage regulator MOSFET (e.g., DrMOS) devices, inductors, capacitors, side edge solder pins and filter capacitors, e.g., to help reduce the total electric current path impedance from the external power source to the die, and High Bandwidth Memory (HBM). Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor IC package is mounted may comprise an add-in card, such as a PCIe card, that is configured to be coupled to a system board or motherboard of a host system. In other embodiments, the PCB to which the semiconductor IC package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

In one example, the processors may include one or more CPUs, GPUs, DPUs, QPUs, a plurality of PPUs, and/or application-specific integrated circuits (ASICs). QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

One aspect of the present disclosure provides a method of improving signal integrity (SI) in high-speed RF (radiofrequency) conducting traces on a substrate. In an example embodiment, the method includes defining specific locations along the traces that are prone to SI reduction due to local surface roughness of the conducting material, and applying a broadband conductive material onto the conducting traces at the defined specific locations to improve the SI. A conducting trace refers to a path or line made of a conductive material on the printed circuit board (PCB) or similar electronic device. These traces are used to electrically connect different components on the board, allowing electrical signals and power to flow between them. The traces act as the “wires” on the PCB, providing the electrical connections between components such as resistors, capacitors, integrated circuits (ICs) including photonic ICs, and other devices.

It should be noted that the local surface roughness, in the context of this disclosure, refers to any property of the conducting medium, in a macroscopic or microscopic dimension, creating reflections or scattering when encountered by a surface plasmon polariton and compromising signal integrity. The local surface roughness may include increased roughness as compared to the characteristic surface roughness of the material, any surface defects, or grain boundaries. The local surface roughness may also be induced by any sharp change in the geometrical shape of the conducting trace (e.g., corners or bends in the design of traces).

The broadband conductive material refers to substances or compounds that possess the ability to conduct electricity across a wide range of frequencies or wavelengths, typically including radio frequencies, microwaves, and even higher frequencies such as infrared and visible light. As used herein, the conducting trace or interconnect features may be conductive portions of circuit board. For instance, the interconnect features may include metal traces, plated and non-plated through-holes, solder points, transmission lines, and electrically-insulating circuit board material over which such copper traces and solder points may lie. An interconnect feature may pass along sides and across the circuit board to contact between computing features, such as a chip-to-chip interconnect, an NVlink® interconnect, a PCIe® high speed communication interconnect, among other interconnects that may exist on a circuit board.

Examples of broadband conductive materials include certain metals (e.g., copper, silver), conductive polymers, and carbon-based materials like graphene. The broadband conductive material is applied (e.g., deposited) over and/or onto a surface of the conducting traces so as to form a coating over and/or on the surface of the conducting traces. The broadband conductive material is configured to have a potential difference with the conducting trace such that surface electrons transfer to the broadband conductive coating, reducing or even preventing the formation of the surface waves such as surface plasmon polaritons (SPPs) and thus reducing the scattering and reflection thereof that would compromise the SI of an RF signal traversing the conducting trace.

One aspect of the present disclosure provides a substrate having conducting traces for high-speed RF (radiofrequency) signals, the substrate further comprising areas of a broadband conductive material applied onto specific locations along the traces that are prone to SI reduction due to possible surface roughness of the conducting material, wherein the broadband conductive material improves a signal integrity (SI) of the RF signals.

Various embodiments comprise semiconductor devices, PCBs and/or IC (integrated circuit) packages comprising the disclosed substrates.

Another aspect of the present disclosure provides a method for fabricating a transmission line configured for providing RF signals with high SI. In an example embodiment, the method includes identifying specific locations along a conducting trace that are prone to SI reduction due to possible surface roughness of the conducting material of the conducting trace; and applying a broadband conductive material onto the specific locations.

According to an example aspect of the present disclosure, an electrical component is provided. In an example embodiment, the electrical component includes at least one conducting trace configured for conducting radiofrequency (RF) signals. The at least one conducting trace has a broadband conductive material applied onto one or more specific locations along the at least one conducting trace.

In an example embodiment, the electrical component further includes a substrate, wherein at least a portion of the at least one conducting trace is disposed on the substrate. In an example embodiment, the broadband conductive material is configured to improve a signal integrity of the RF signals transmitted along the at least one conducting trace compared to if the broadband conductive material was not present. In an example embodiment, each of the one or more specific locations is defined by at least one of a detected surface roughness of the at least one conducting trace at the at least one specific location, a change in direction of the at least one conducting trace with respect to design and/or lithographic parameters, or a change in direction of the at least one conducting trace on a substrate hosting the at least one conducting trace. In an example embodiment, the broadband conductive material comprises graphene. In an example embodiment, the one or more specific locations constitute less than 10% of the surface area of the at least one conducting trace. In an example embodiment, the electrical component is at least one of a semiconductor device, a printed circuit board, or an integrated circuit package.

According to another aspect, a method for fabricating an electrical component is provided. In an example embodiment, the method includes applying a broadband conductive material to one or more specific locations along a conducting trace. Each specific location of the one or more specific locations was identified based at least in part on an anticipated or detected surface roughness of the specific location.

In an example embodiment, the method further includes defining the specific location along the conducting trace based at least in part on the anticipated or detected surface roughness at the specific location. In an example embodiment, the defining of the specific location comprises inspecting the conducting trace for surface roughness and detecting specific locations along the conducting trace having a surface roughness that satisfies an action threshold. In an example embodiment, the defining of the specific location comprises identifying a location corresponding to a change in direction of the conducting trace with respect to design and/or lithographic parameters. In an example embodiment, the defining of the specific location comprises inspecting the conducting trace to detect changes in direction of the conducting trace on a substrate hosting the conducting trace.

In an example embodiment, applying the broadband conductive material onto the one or more specific locations along the conducting trace comprises patterning a masking on a substrate hosting the conducting trace such that unmasked regions are formed at the one or more specific locations and masked regions are formed on portions of the substrate that are not the one or more specific locations, and depositing the broadband conductive material onto the unmasked regions that correspond to the one or more specific locations. In an example embodiment, the method further includes removing the mask while leaving the broadband conductive material on the one or more specific locations.

In an example embodiment, the broadband conductive material comprises graphene. In an example embodiment, the one or more specific locations constitute less than 10% of the surface area of the at least one conducting trace. In an example embodiment, the method further includes prior to applying the broadband conductive material to the one or more specific locations, determining an SI of the conducting trace; and after applying the broadband conductive material to the one or more specific locations, verifying an improvement of the SI of the conducting trace following the application of the broadband conductive material. In an example embodiment, the method further includes identifying one or more locations with persisting SI reduction based on the verifying of the improvement of the SI of the conducting trace; and reiterating the application of the broadband conductive material at the one or more locations with persisting SI reduction.

According to another aspect, a circuit formed at least in part on a substrate is provided. In an example embodiment, the circuit includes a conducting trace that has a broadband conductive material applied onto one or more specific locations along the conducting trace.

In an example embodiment, the one or more specific locations correspond to areas of expected or detected surface roughness of the conducting trace and the one or more specific locations constitute less than 10% of the surface area of the at least one conducting trace. In various embodiments, the circuit is part of at least one of a semiconductor device, a printed circuit board, or an integrated circuit package.

Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

These, additional, and/or other aspects and/or advantages of the present disclosure are set forth in the detailed description which follows, possibly inferable from the detailed description, and/or learnable by practice of the present disclosure.

### BRIEF DESCRIPTION OF THE DRAWINGS

For a better understanding of embodiments of the disclosure and to show how the same may be carried into effect, reference will now be made, purely by way of example, to the accompanying drawings in which like numerals designate corresponding elements or sections throughout. In the accompanying drawings:

FIGS. 1A-1D are high-level schematic illustrations of the process of improving signal integrity (SI) in high-speed RF (radiofrequency) conducting traces on a substrate, according to some embodiments of the disclosure.

FIG. 1E is a high-level highly schematic illustration of a semiconductor device, a printed circuit board and an integrated circuit package comprising disclosed electrical component, according to some embodiments of the disclosure.

FIGS. 2A and 2B are high-level flowcharts illustrating methods of improving SI in high-speed RF conducting traces on a substrate, according to some embodiments of the disclosure.

FIGS. 3A and 3B provide examples for locations having or prone to surface roughness on traces, according to some embodiments of the disclosure.

FIG. 4 is a high-level schematic illustration of a lithographic masking method, according to some embodiments of the disclosure.

FIG. 5 illustrates an example computer system that may include electrical components, according to at least one embodiment.

FIG. 6 provides a block diagram that schematically illustrates a computing system that may include one or more electrical components of various embodiments.

FIG. 7 illustrates an example computing environment that may include electrical components, in accordance with at least one embodiment.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE DISCLOSURE

In the following description, various aspects of the present disclosure are described. For purposes of explanation, specific configurations and details are set forth in order to provide a thorough understanding of the present disclosure. However, it will also be apparent to one skilled in the art that the present disclosure may be practiced without the specific details presented herein. Furthermore, well-known features may have been omitted or simplified in order not to obscure the present disclosure. With specific reference to the drawings, it is stressed that the particulars shown are by way of example and for purposes of illustrative discussion of the present disclosure only, and are presented in the cause of providing what is believed to be the most useful and readily understood description of the principles and conceptual aspects of the disclosure. In this regard, no attempt is made to show structural details of the disclosure in more detail than is necessary for a fundamental understanding of the disclosure, the description taken with the drawings making apparent to those skilled in the art how the several forms of the disclosure may be embodied in practice.

Before at least one embodiment of the disclosure is explained in detail, it is to be understood that the disclosure is not limited in its application to the details of construction and the arrangement of the components set forth in the following description or illustrated in the drawings. The disclosure is applicable to other embodiments that may be practiced or carried out in various ways as well as to combinations of the disclosed embodiments. Also, it is to be understood that the phraseology and terminology employed herein are for the purpose of description and should not be regarded as limiting.

Some embodiments of the present disclosure provide efficient and economical methods and mechanisms for improving signal integrity (SI) in high-speed RF (radiofrequency) circuits and thereby provide improvements to the technological field of signal transmission. Methods of improving SI in high-speed RF conducting traces on a substrate, and corresponding substrates are provided. Substrates comprise areas of a broadband conductive material applied onto specific locations along the traces that are prone to SI reduction due to possible surface roughness of the conducting material. Following definition and/or detection of the specific locations, conductive material is deposited locally to improve the SI while avoiding short circuiting the conducting traces, thereby improving the SI of the RF signals. Disclosed embodiments overcome the reduction of SI caused by surface roughness at specific locations along the conducting traces, possibly by caging surface plasmon polaritons (SPPs) that are excited by the RF electric field and preventing signal reflection and scattering caused by the SPPs at the specific locations. Additional functional layer(s) in the production process may be implemented to deposit the broadband conductive material over specific areas prone to SI losses in the design. In some embodiments, the broadband conductive material is applied to cover surface defects in conducting traces of PCB (printed circuit board) circuits and improve the SI.

In general, the local surface roughness of a conduit or electrical path for providing RF signals, such as a conducting trace, may affect the signal integrity of the RF signals conducted there along. The signal integrity may be specifically affected in areas on the surface of the conducting material which form a type of surface wave. The surface wave may be guided along the interface between the conductive trace and the adjacent medium, termed Surface Plasmon Polaritons (SPPs). This propagation ends when the SPP's energy is lost, either to absorption in the material of the conductive trace or the adjacent medium or by scattering into other directions. These scatterings cause losses of SI. Therefore, technical problems exist in electrical components comprising conducting traces and methods for fabrication thereof.

Various embodiments provide technical solutions to these technical problems. In various embodiments, a broadband, electrically conductive material is applied over specific locations along conducting traces. The specific locations are identified as locations along the conducting trace having surface defects and/or local roughness (where the scattering and reflections are most pronounced). Application of the broadband electrically conductive material reduces the scattering and reflection of an RF signal propagating along the conducting trace such the effect of RF signal scattering and/or reflection on the SI of the RF signal is reduced. Application of the broadband conductive material over traces made of a conductive material may effectively reduce the surface roughness of the conducting trace, and thus reduce scattering of the SPPs. It should be noted that, in certain embodiments, the broadband electrically conductive material can cause electrical shortage when deposited over the entire conducting trace, substrate that hosts the conducting trace, or PCB. Thus, in such embodiments, the broadband electrically conductive material should be applied selectively to areas that might cause scattering, reflection, and/or SI compromise.

Therefore, various embodiments provide technical advantages to the fields of electrical components, systems that include the electrical components, and methods for fabrication of electrical components and systems that include the electrical components.

### Example Electrical Component

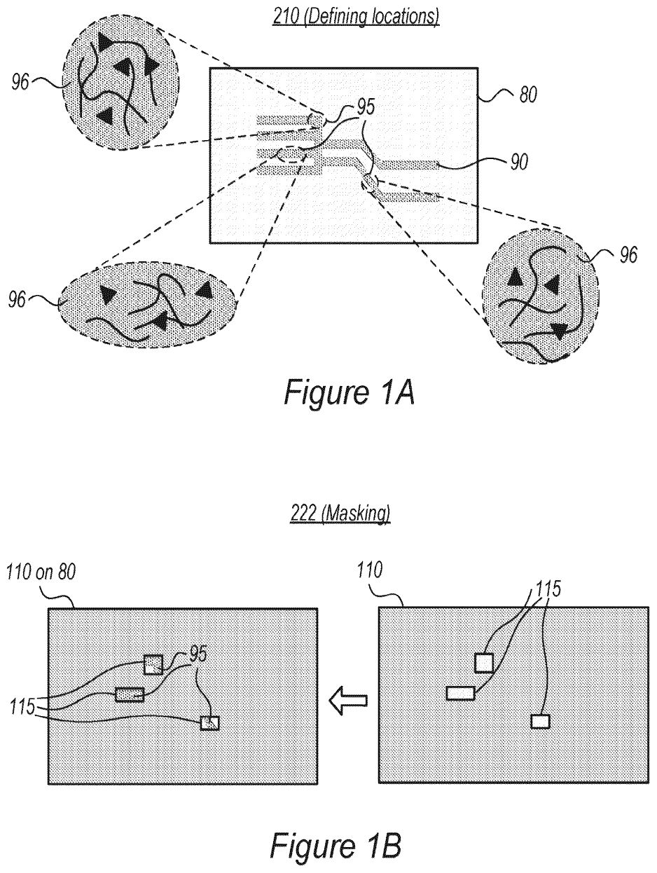

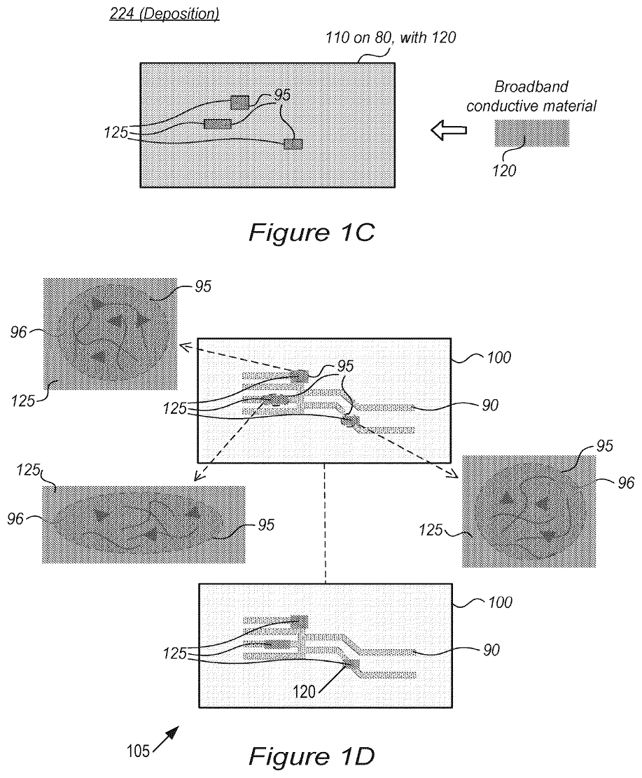

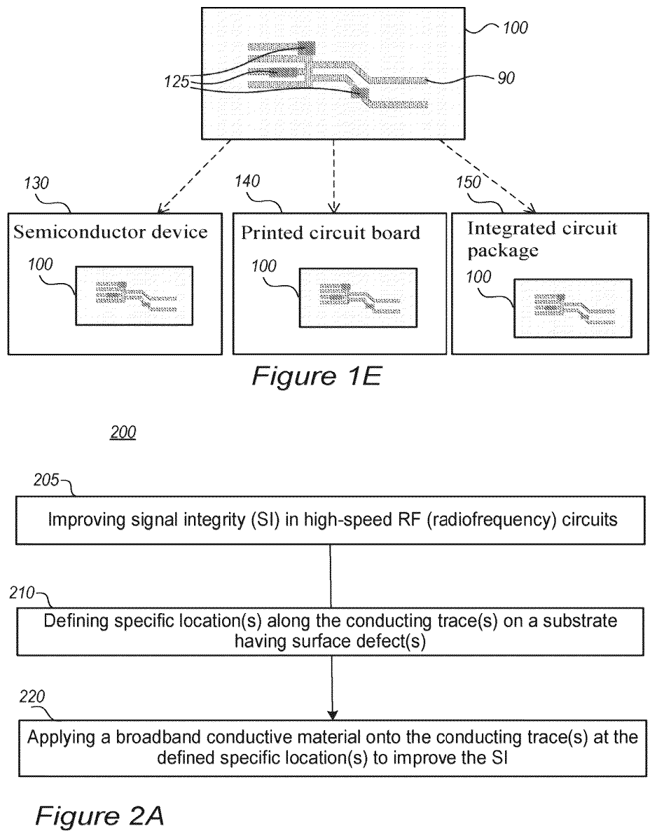

FIGS. 1A-1D provide high-level schematic illustrations of improving signal integrity (SI) in high-speed RF (radiofrequency) conducting traces 90 on a substrate 80, according to some embodiments of the disclosure. As shown in FIG. 1D, an electrical component 105 of an example embodiment includes at least one conducting trace 90 formed at least in part on a substrate 100 and having a broadband conductive material 120 applied to one or more specific locations 95 along the conducting trace 90. In certain embodiments the substrate 100 is a printed circuit board (PCB) a silicon wafer and/or the like and conducting traces 90 are configured for conducting for high-speed radiofrequency (RF) signals. In various embodiments, the broadband conductive material 120 is applied onto specific locations 95 along a conducting trace 90 that are prone to signal integrity (SI) reduction due to possible surface roughness of the conducting material of the conducting trace 90.

For example, some portions of conducting traces 90 may have increased surface roughness 96 (e.g., due to various reasons including material quality, trace geometry, deposition quality, accidental damage, etc.). Surface roughness 96 is illustrated in a highly schematic manner in FIG. 1A, and may include unsmooth surface regions, local and surface defects, boundaries between crystal grains (even in high quality conductors), production artefacts, etc. This surface roughness 96 may negatively affect the SI of high-speed RF signals conducted along the conducting traces 90. For example, locations with higher surface roughness 96 may cause signal integrity problems by causing reflections and scattering of the RF signal in the high-speed conducting traces. These issues may result from the skin effect, in which the high frequencies of the RF signal travel close to the surface and may thus be affected, e.g., reflected and scattered by surface roughness 96. In addition, the RF electric field creates surface waves, such as surface plasmon polaritons (SPPs, e.g., collective oscillations of free electrons at the metal-dielectric interface excited by the RF electric field), that may travel in multiple frequencies and may undergo reflection and scattering, especially when encountering surface defects as in locations exhibiting surface roughness 96. These reflections and scatterings can compromise the signal integrity of RF signals conducted along the conducting traces 90. For example, SPP reflection and scattering at specific locations 95 of surface roughness 96 may yield dip(s) in the transmission curve at specific frequencies, which may cause significant reduction of the SI and hinder data transmission.

In certain embodiments, the broadband conductive material 120 is applied to specific locations 95 of conducting traces 90 such that the applied broadband conductive material 120 is configured to improve a signal integrity of the RF signals transmitted along the at least one conducting trace 90 compared to if the broadband conductive material was not present. For example, the one or more specific locations 95 may each be defined and/or identified based on a detected surface roughness 96 of the at least one conducting trace 90 at the at least one specific location, a change in direction of the at least one conducting trace with respect to design and/or lithographic parameters, and/or a change in direction of the at least one conducting trace on a substrate hosting the at least one conducting trace.

In some embodiments, the broadband conductive material 120 comprises graphene or another material that possess the ability to conduct electricity across a wide range of frequencies or wavelengths, such as radio frequencies, microwaves, and possibly higher frequencies such as infrared and visible light. broadband conductive material 120 may comprise graphene sheets or patches. Non-limiting examples for broadband conductive materials 120 include graphene in various forms, e.g., single layered (monolayer) graphene, multiple layered graphene (including two or more layers) as well as composite graphene materials (e.g., graphene flakes within a matrix, e.g., in a polymeric matrix). In some embodiments, carbon nanotubes may be applied, possibly within a matrix, to form the coating. In various embodiments, different types of defects (in size and geometry) may be handled by different types of material (layered, composite etc.) and deposition method.

In various embodiments, the conducting traces 90 are formed of a conducting material. In various embodiments, of the conducting material is a metal (e.g., copper, gold, silver, platinum, and/or an alloy thereof. In an example embodiment, the conducting material is ultra-smooth copper which has a density of rough peaks exceeding 0.5 μm that is quite low (e.g., 0.01 features exceeding 0.5 μm per square micron or less). Ultra-smooth copper may be used in embodiments where the electrical component 105 is configured for use in and/or as part of high frequency electronics (e.g., for conducting RF signals characterized by frequencies of 10 GHz or higher).

In various embodiments, the one or more specific locations 95 amount to and/or constitute less than 10% of the surface area of the conducting trace 90. For example, the surface area of the conducting trace 90 and/or substrate 100 covered by patches 125 of broadband conductive material 120 is small enough to prevent short circuiting of the conducting trace 90 and/or prevent unintendedly placing the conducting trace 90 into electrical communication with another component formed at least in part on the substrate 100.

In certain embodiments, the specific locations 95 constitute less than 10%, less than 5% or less than 1% of the surface area of the conducting traces 90. In certain embodiments, the areas of deposited broadband conductive material 120 constitute less than 10%, less than 5% or less than 1% of the surface area of the conducting traces 90. It is noted that the extent of conductive material deposition over the specific locations 95 with respect to the length and/or surface area of conducting traces 90 is kept low (e.g., specific locations 95 may constitute less than 10%, less than 5% or less than 1% of the length or surface area of the conducting traces 90) in order not to short-circuit conducting traces 90.

In various embodiments, the electrical component 105 is and/or is part of a semiconductor device 130, a printed circuit board 140, or an integrated circuit package 150.

Deposition of broadband conductive material 120 at specific locations 95 improves the signal integrity (SI) of the RF signals conducted through conducting traces 90. As illustrated schematically in FIG. 1A, a substrate 80 (numeral 80 denoting the substrate before deposition of broadband conductive material 120, while numeral 100 denotes the substrate after the deposition, e.g., PCB) may support multiple high-speed RF conducting traces 90, which may have a complex geometries including corners, bends, connections (internal and external), etc.

In various embodiments, patches 125 of broadband conductive material 120 are applied to specific locations 95 identified and/or defined as locations along a conducting trace 90 at which surface roughness 96 has been detected or is anticipated (e.g., based at least in part on a planned or fabricated geometry of the conducting trace 90). The patches 125 of broadband conductive material 120 provide a conductive route portions of the RF signal that tend to travel close to the surface of conducting traces and therefore prevent reflections or scatterings caused by interaction of portions of the RF signal with the surface roughness 96. For example, the signal integrity of a conducting trace 90 is improved by the application of broadband conductive material 120 to specific locations 95 along the conducting trace 90 where surface roughness 96 has been detected or is anticipated. Therefore, various embodiments provide technical advantages to the fields of electrical components, systems that include the electrical components, and methods for fabrication of electrical components and systems that include the electrical components.

Various embodiments provide electrical components 105 including conducting traces 90 which have had broadband conductive material 120 applied to specific locations 95 along the conducting trace 90. Various embodiments include semiconductor devices 130, PCBs 140 and/or IC packages 150 that comprise disclosed electrical components 105.

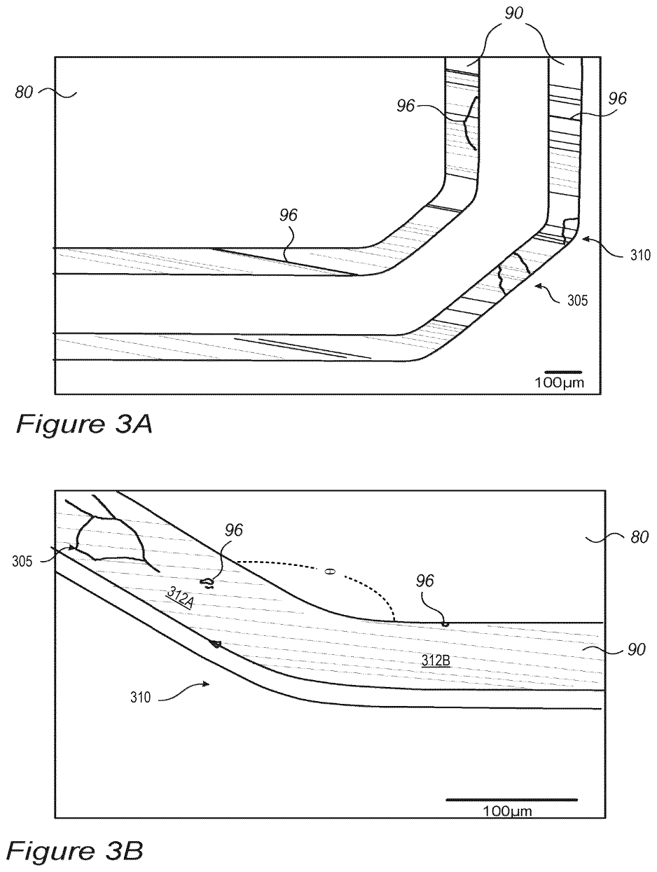

FIGS. 3A and 3B provide schematic examples for specific locations 95 (e.g., edges, bends, large grain boundaries) that may be anticipated to have (e.g., are prone to) surface roughness 96 on conducting traces 90, according to some embodiments of the disclosure. For example, grain boundaries 305 and trace bends 310 illustrated schematically in FIGS. 3A and 3B which are prone to higher surface roughness 96.

Specific locations 95 prone to surface roughness 96 on conducting traces 90 may be detected using various inspection methods such as ellipsometry, profilometry, optical microscopy and/or scanning electron microscopy (SEM). For small, designated specific locations 95, atomic force microscopy (AFM) may be used to achieve higher resolutions. These methods can be used in an automated manner, such as automatic visual scanning and inspection followed by automatic image processing to detect specific locations 95 on produced conducting traces 90, e.g., as part of the production procedure.

Surface roughness 96 may be defined, characterized and measured in various ways, which take into account the effects roughness has on the SI (e.g., the rougher the copper or other conductive material of the conducting trace 90 is, the more local spikes it has on the surface, causing more significant reduction of the SI) and/or the types of sources for roughness and their expanse, e.g., grain boundaries, corners or changes in direction in the conducting traces 90, etc.—some of which relate to design issues and other to production issues.

Several parameters may be used to calculate the surface roughness according to the surface conducting trace shape as measured by the relevant techniques mentioned herein. One example parameter for measuring surface roughness is R_{q} or R_{RMS} (Root Mean Square Roughness), the square root of the average of the squares of the surface height deviations from the mean line of the surface of the conducting trace. In other words, the R_{q} or R_{RMS} is the root mean square of the surface height deviations and provides more sensitivity to peaks and valleys than other commonly used parameters. The R_{q} or R_{RMS} may be used in applications where the effects of peaks and valleys are more critical, and is calculated as the root mean square average of the surface profile along the x-axis-denoted Z(x)—over the sample length—denoted lr, as in Equation 1:

$${R}_{q} ∝ \sqrt{\frac{1}{lr} {\int }_{0}^{lr} {Z}^{2} ( x ) dx} \qquad Equation 1$$

For signal frequencies greater than about 10 GHz, the surface roughness becomes more important (compared to signal frequencies below 10 GHz) due to the skin effect and the large amount of scattering events, reflections, etc. Ultra-smooth conductive material used for fabricating the conducting traces 90 (e.g., ultra-smooth copper) configured for high frequencies generally refers to an RMS roughness value of less than 0.5 um. As signal frequency increases (e.g., increasing above 10 GHZ), desired values for RMS roughness are even lower. For example, in various embodiments, it is desired to have RMS roughness of the surface of conducting traces 90 less than 500 nm.

For RF frequencies, the skin effect exists in the conductive material used to form the conducting traces 90 (e.g., copper), where the current is passed in the periphery close to the surface rather than in the bulk of the conductive material. The higher the signal frequencies, the stronger the skin effect, meaning less effective medium for the current to pass through and much higher sensitivity to surface features. For example as signal frequencies increase, a greater portion of the current cross-section is located adjacent or near the surface of the conducting traces 90. In addition, the multiple frequencies existing in RF signals, including reflections, scattering, surface waves etc. along the conducting traces 90, produce a more complex system where the surface roughness of a conducting trace 90 affects the signal integrity of the conducting trace 90. Surface defects are characterized by an uneven surface with “spikes” that reduce the flatness or uniformity of the surface of the conducting trace 90. Surface roughness or topological features of the surface of the conducting traces 90 can arise at areas such as grain boundaries, where the conductive material lattice is uneven and two different crystallographic orientations meet throughout the grain boundary in the bulk of the material all the way to the surface of the conductive trace. Corners and edges (e.g., places where a conducting trace 90 changes direction) are also prone to defects. An impurity in the conductive material located on the surface of the conducting trace will also cause higher roughness.

Accordingly, in various embodiments, specific locations 95 on conducting traces 90 on the substrate 80 at which depositing broadband conductive material 120 is expected to improve the SI of signals conducted along the conducting traces 90, may be defined and/or identified based at least in part on detected surface roughness of conducting traces 90, changes in direction of conducting traces 90 with respect to design and/or lithographic parameters used to fabricate the conducting traces 90, and/or by changes in direction of conducting traces 90 on substrate 80. These areas of detected and/or anticipated surface roughness 96 and that are prone to SI issues may be detected by high magnification optical microscopy, or by scanning electron microscopy (SEM) if higher resolution is required. Detection and location defining processes and/or stage(s) may be integrated into regular substrate inspection processes, or may be carried out as additional inspection steps, e.g., following the fabrication of at least some, or groups of conducting traces 90 on substrate 80 and/or following any fabrication process that might cause surface roughness on a surface of a conducting trace 90.

Once the areas of surface roughness 96 are identified based on detected and/or anticipated surface roughness, the specific locations 95 may be defined based thereon. The patches 125 of broadband conductive material 120 may then applied to the specific locations 95 to provide an electrical component including at least one conducting trace 90 having broadband conductive material applied to one or more specific locations 95 along the at least one conducting trace 90.

FIG. 1E is a high-level highly schematic illustration of a semiconductor device 130, a printed circuit board 140 and an integrated circuit package 150 comprising disclosed electrical components 105, according to some embodiments of the disclosure. Disclosed electrical components 105 may be used in any type of semiconductor device 130, printed circuit board (PCB) 140, and/or integrated circuit (IC) package 150 to improve the respective SI in high-speed RF conducting traces 90 on respective substrates 100, in a broad range of implementations.

### Example Method of Fabrication

As noted above, in various embodiments, fabricating an electrical component 105 of an example embodiment includes defining specific locations 95 along the conducting trace 90 based, for example, on detected and/or anticipated surface roughness 96, and then applying a broadband conductive material onto the conducting traces 90 at the specific locations 95.

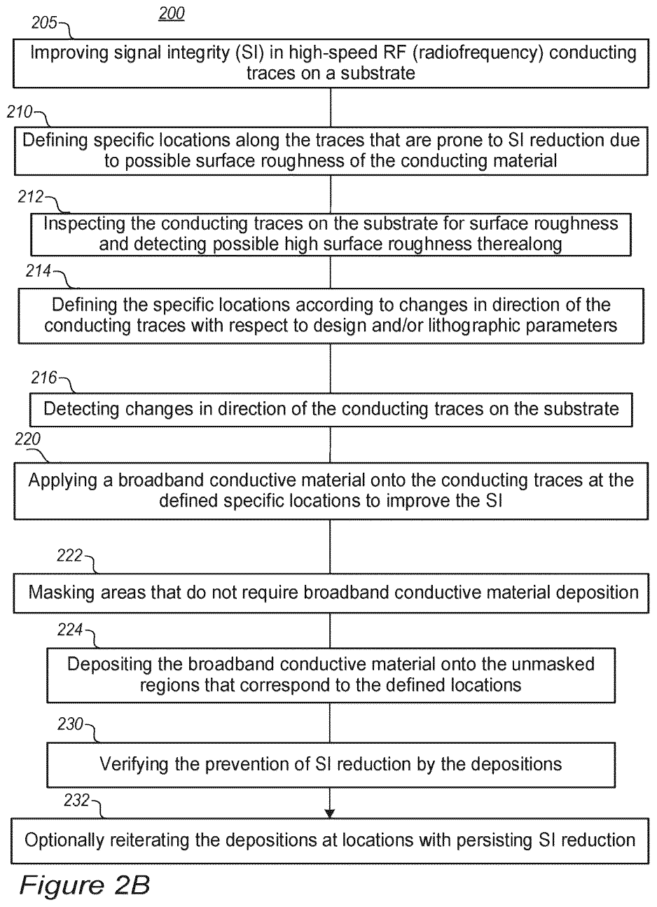

FIGS. 2A and 2B illustrate an example method 200 for fabricating electrical components of various embodiments. In various embodiments, the method 200 is configured to improve the signal integrity in high-speed RF circuits 205 of electrical components by defining specific locations 95 along conducting traces 90 of the RF circuits and/or of the electrical components that are detected and/or anticipated to have surface roughness 96 that satisfies an action threshold (at block 210) and applying broadband conductive material 120 to the specific locations 95 (at block 220). In various embodiments, the surface roughness 96 of a portion of a conducting trace 90 satisfies the action threshold when the RMS roughness is greater than or equal to an action threshold value. In some embodiments, the action threshold value is in a range of 200 nm to 500 nm.

Method 200 may comprise carrying out the defining the specific locations (block 210) using a variety of techniques. For example, as shown in FIG. 2B, defining the specific locations may include inspecting the conducting traces 90 on the substrate for surface roughness and detecting locations along the conducting traces 90 having a surface roughness that satisfies an action threshold (at block 212). For example, locations along the conducting traces 90 having a surface roughness that satisfies the action threshold may be detected using various inspection methods such as ellipsometry, profilometry, optical microscopy and/or scanning electron microscopy (SEM). For small, designated areas, atomic force microscopy (AFM) may be used to achieve higher resolutions. These methods can be used in an automated manner, such as automatic visual scanning and inspection followed by automatic image processing to detect locations along the conducting traces 90 having a surface roughness that satisfies the action threshold, e.g., as part of the production procedure.

Alternatively or additionally, in some embodiments, defining the specific locations 95 includes identifying locations along the conducting traces 90 where the conducting traces 90 change in direction with respect to design and/or lithographic parameters (block 214). For example, design and/or lithographic parameters used to fabricate the conducting traces 90 may be analyzed to identify locations along the conducting traces 90 where conducting traces change direction. In various embodiments, a conducting trace 90 is identified as changing direction when an angle θ between a first section 312A of the conducting trace 90 and a second section 312B of the conducting trace 90 satisfies an angle change threshold. In various embodiments, the angle θ between a first section 312A of the conducting trace 90 and a second section 312B of the conducting trace 90 satisfies the angle change threshold when the angle θ is in a range of 0 to 175 degrees or in a range of 185 to 360 degrees.

Alternatively or additionally, in some embodiments, defining the specific locations 95 includes detecting locations along the conducting traces 90 where the conducting traces 90 formed on the substrate change directions (block 216). For example, based on imaging of the conducting traces 90 formed on the substrate 80, locations where the conducting traces 90 change directions may be identified and/or detected. For example, an image of the conducting trace 90 may be analyzed (e.g., using an automated/computer vision technique or via human inspection) to identify and/or detect locations where the conducting trace 90 changes directions. In various embodiments, a conducting trace 90 is identified as changing direction when an angle θ between a first section 312A of the conducting trace 90 and a second section 312B of the conducting trace 90 satisfies an angle change threshold. In various embodiments, the angle θ between a first section 312A of the conducting trace 90 and a second section 312B of the conducting trace 90 satisfies the angle change threshold when the angle θ is in a range of 0 to 175 degrees or in a range of 185 to 360 degrees.

After the specific location 95 are defined, the broadband conductive material is applied to the conducting traces 90 at the specific locations 95 at block 220. In various embodiments, applying the broadband conductive material 120 to the conducting traces 90 includes forming and/or patterning a mask on the substrate 80 such that unmasked regions are formed at the one or more specific locations 95 and masked regions are formed on portions of the substrate 80 that are not the one or more specific locations 95, at block 222.

As schematically illustrated in FIGS. 1B-1D, a mask may be patterned on the substrate 80 that masks areas that do not require broadband conductive material deposition. Masking areas that do not require broadband conductive material deposition may comprise designing the mask to avoid exposed margins around the respective traces from covering adjacent traces or conductive features on the substrate 80—to prevent short-circuits.

For example, FIG. 1B illustrates schematically a mask 110, placed over substrate 80, having openings 115 over specific locations 95 which were identified to exhibit excessive surface roughness, and/or defined as potentially causing reduction of SI, as disclosed herein. In various embodiments, mask 110 with openings 115 may be designed in parallel to the design of the circuit(s) including conducting traces 90 (e.g., with openings 115 defined to overlap corners or bends in the design of conducting traces 90) and/or after production of examples of substrate 80, on which actual resulting surface roughness at specific locations along conducting traces 90 are detected. Alternatively or complementarily, mask 110 with openings 115 may be designed and applied as an ad hoc solution, e.g., after accidental damage is found to cause defects that reduce the SI at specific locations 95 along conducting traces 90. The mask 110 may comprise a hard, or shadow mask (made, e.g., of metal, hard photoresist, or polymer), that covers the substrate 80 and has windows or openings 115 therethrough that expose only the areas that are to be coated (e.g., the specific locations 95) by the broadband conductive material 120. The mask 110, through which broadband conductive material 120 is applied—is designed such that the margins around respective conducting traces 90 do not cover adjacent traces or conductive features on substrate 80—to prevent short-circuit.

At block 224, the broadband conductive material is deposited onto the unmasked regions (e.g., through windows or openings 115) that correspond to the specific locations 95. For example, once the shadow mask is placed on the substrate 80 aligned with the design and/or conducting traces 90, application of the broadband conductive material takes place using a method relevant to the broadband conductive material. For example, in various embodiments, the broadband conductive material 120 may be deposited as a spray coat, via an adhesive tape transfer, by dipping the substrate 80 into the broadband conductive material 120, by brushing the broadband conductive material 120 onto the substrate 80, and/or the like.

FIG. 1C further illustrates schematically the deposition of broadband conductive material 120 at openings 115 of mask 110, over specific locations 95, yielding patches 125 of broadband conductive material 120. The extent of openings 115 in mask 110 is kept small and the location and distribution of openings 115 is configured to prevent short-circuits between conducting traces 90 by shielding most of the design and/or substrate 80 from deposited broadband conductive material 120.

In various embodiments, application of broadband conductive material 120 onto specific locations 95 may be carried out by various means such as spray coating, dipping, brushing, micro-manipulation of thin films, and/or the like, according to the specifications and properties of broadband conductive material 120—to form patches 125 of broadband conductive material 120 that improve the SI of RF signals conducted along the conducting traces 90. The distribution of patches 125 of broadband conductive material 120 may be defined as an additional layer or step in deposition or lithography processes, which define the distribution of openings 115 in one or more mask(s) 110, possible at different stages of production in which different layers with conducting traces 90 are deposited or printed.

In some embodiments, the mask 110 is removed after the broadband conductive material 120 is deposited therethrough. For example, the mask 110 may be made of a material that may be selectively and/or chemically etched and/or removed off of the substrate 100 without degrading the patches 125 of broadband conductive material 120, the conducting traces 90, or other components formed on and/or hosted by the substrate 100.

Finally, FIG. 1D illustrates schematically resulting substrate 100 with patches 125 of broadband conductive material 120 applied onto specific locations 95 along conducting traces 90—improving the SI for conducting traces 90 and the circuits containing them. It is understood that FIG. 1D is highly schematic, as the shapes and distribution of patches 125 may be configured in different ways that optimize the improvement of the SI while avoiding short-circuiting conducting traces 90 to any adjacent conductive features on substrate 80.

In various embodiments, method 200 may further comprise verifying the improvement of the SI of RF signals conducted along the conducting trace 90 following the application of the broadband conductive material 120 to one or more specific locations along the conducting trace 90, at block 230. For example, prior to depositing the broadband conductive material 120 (e.g., possibly prior to or during performance of block 210), a known RF signal may be conducted along a conducting trace 90 and an SI of the RF signal may be determined. After deposition of the broadband conductive material 120 to the specific locations along the conducting trace 90, the process may be repeated to determine the improved SI of RF signals conducted along the conducting trace 90. In some embodiments, the pre-deposition SI is compared to the post-deposition SI to determine and/or verify that the SI reduction is prevented by the broadband conductive material 120 applied to the specific locations 95. For example, when the improvement in the SI between the pre-deposition SI and the post-deposition SI satisfies a threshold SI improvement (e.g., is greater than or equal to a threshold value of SI improvement), it may be determined that the SI reduction is prevented by the broadband conductive material 120 applied to the specific locations 95.

In some embodiments, verifying that the SI reduction is prevented by the broadband conductive material 120 applied to the specific locations 95 includes determining an SI of an RF signal conducted along the conducting trace 90 after the application of the broadband conductive material 120 is applied to the specific locations 95 and determining whether that SI satisfies an SI threshold. In an example embodiment, the SI satisfies an SI threshold when the SI is greater than or equal to a threshold SI value.

In some embodiments, at block 232, blocks 210 and/or 220 are repeated to identify any remaining or persisting specific locations 95 characterized by surface roughness 96 and mitigating the surface roughness thereof via application of broadband conductive material 120 thereto. For example, in some embodiments when the improvement in the SI between the pre-deposition SI and the post-deposition SI does not satisfy a threshold SI improvement (e.g., is less than the threshold value of SI improvement) and/or when the post-deposition SI does not satisfy an SI threshold (e.g., the post-deposition SI is less than the threshold SI value), a reiteration of the depositions of the broadband conductive material at specific locations with persisting SI reduction and/or persisting surface roughness may be performed.

Method 200 may be at least partially implemented by at least one computer processor, e.g., in an inspection, optimization and/or fabrication system. Certain embodiments comprise computer program products comprising a non-transitory computer readable storage medium having computer readable program stored therein and configured to, when executed by one or more processors of an apparatus, cause the apparatus to carry out the relevant stages of method 200.

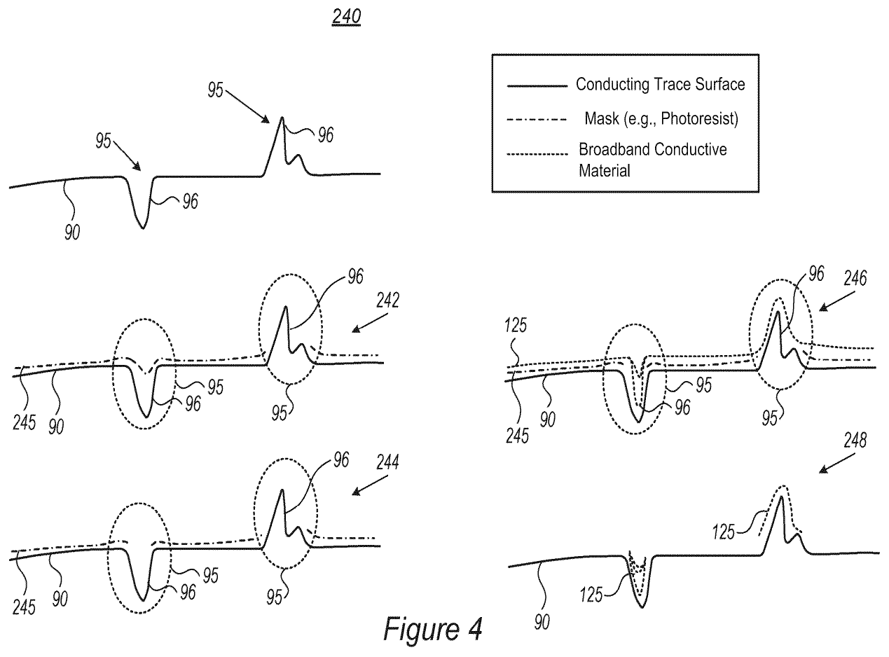

FIG. 4 is a high-level schematic illustration of a lithographic masking method 240, according to some embodiments of the disclosure. In various embodiments, the lithographic masking method 240 is to apply a broadband conductive material onto the conducting trace(s) at the defined specific location(s) to improve the SI (e.g., at block 220). In various embodiments, the lithographic masking method 240 comprises, at stage 242, applying a very thin layer of photoresist 245, e.g., having a thickness of up to the scale of the defect size-over at least a part, or over whole of substrate 80 and/or over specific conducting traces 90 including specific locations 95 that are prone to surface roughness (as identified by inspection, and/or suspected by design). Due to the thinness of photoresist layer 245, surface roughness 96 in specific locations 95 (with a degree of roughness that passes a threshold related to the type and thickness of photoresist layer 245) results in discontinuities in photoresist layer 245—forming exposed areas at specific locations 95 illustrated schematically in stage 242. These discontinuities in the photoresists layer 245 may be enhanced and/or fixated by baking and rinsing of the photoresist at the discontinuities, at stage 244. The baking and rinsing of the photoresist at the discontinuities may forming small openings in the photoresist layer 245.

A local application of broadband conductive material 120 is carried out at stage 246 via the openings in the photoresist layer 245. The broadband conductive material 120 may be applied over the remaining photoresist. Via the openings at the specific locations 95, the broadband conductive material 120 coats defects of surface roughness 96 directly at the specific locations 95. Upon liftoff of the resist (illustrated schematically in stage 248), the specific locations 95 having surface roughness 96 remain covered by broadband conductive material 120 to reduce their roughness and/or improve the SI by preventing or reducing SI reduction due to surface roughness 96 and/or surface defects, while the rest of the surface is cleared of both photoresist and broadband conductive materials 245, 120, respectively.

As a non-limiting example, the resist thickness for photolithographic process of broadband material application (e.g., as illustrated in FIG. 4) is selected to be low enough such that the defect spike/dip creates a local hole in the photoresist for the local deposition of broadband conductive material 120, as described herein. For example, the photoresist thickness may be around the same size or slightly smaller than the dimensions of features of the surface roughness 96. For example, for a conducting trace 90 having locations with R_{RMS}>500 nm (R_{q} in terms of Equation 1) and the specific location (e.g., the surface defect at the specific location) having a radius of about 0.5 μm, the thickness of applied patches 125 of broadband conductive material 120 may be between 200-500 nm. The coverage of the specific location 95 by broadband conductive material 120 may extend up to 50% beyond the size of the respective area and/or surface defect area, as long as no short loops are created on the substrate by broadband conductive material 120 (e.g., as long as the broadband conductive material does not short circuit the conducting trace 90). For example, the coverage of the specific location 95 by the broadband conductive material 120 may be determined based at least in part on the geometry of the conducting traces 90 on the substrate 80. For example, if two conducting traces 90 or two portions of the same conducting trace 90 are located near one another proximate a specific location 95, the coverage of the specific location 95 by the broadband conductive material 120 may be more fitted to the specific location 95 and/or the patch 125 may be smaller than when there are no other conducting traces 90 or other elements of the electrical component 105 proximate the specific location 95. In various embodiments, more accurate coverage of specific locations 95 having surface roughness 96 by broadband conductive material 120 may be applied to prevent forming short loops and/or to prevent short circuiting of the conducting trace 90.

In various embodiments, applying a broadband conductive material onto the conducting trace(s) 90 at the defined specific location(s) 95 to improve the SI (block 220) may comprise as an alternative or in addition to previously-described methods-three-dimensional (3D) printing of broadband conductive material 120 over specific locations 95 to be covered—to reduce the SI reduction caused by surface roughness 96 at the specific locations 95. 3D printing may be used to deposit broadband conductive material 120 at specific locations, possibly with respect to the improvements achieved in SI following previous deposition, by any of the disclosed methods.

Broadband conductive material 120 may be deposited onto specific locations 95 as a single layer two-dimensional (2D) material, as a few layer 2D material, as multilayer 2D material and/or as a composite material (e.g., paste, powder etc.). Additional examples for broadband conductive material 120 comprise black phosphorus (a 2D material that can be tuned according to the number of layers), carbon nanotubes, MXenes (a family of 2D materials derived from transition metal carbides, nitrides, or carbonitrides, which exhibit excellent electrical conductivity and hydrophilicity, making them suitable for a range of applications including electromagnetic interference shielding) and/or 2D intercalated materials.

Layers may be applied by micromanipulators or thermal release tapes. Pastes or coatings may be applied by various methods such as brushing, spray coating, or applying pressure, e.g., using processes described herein.

Elements from FIGS. 1A-4 may be combined in any operable combination, and the illustration of certain elements in certain figures and not in others merely serves an explanatory purpose and is non-limiting.

### Example Systems Including Electrical Components

In various embodiments, electrical components 105 are incorporated into various systems. For example, various electrical components 105 may be incorporated into datacenters, processing units, ICs, systems on and/or including PCBs, optical interconnects, and/or the like. Some example systems that may include electrical components 105 of various embodiments are now described.

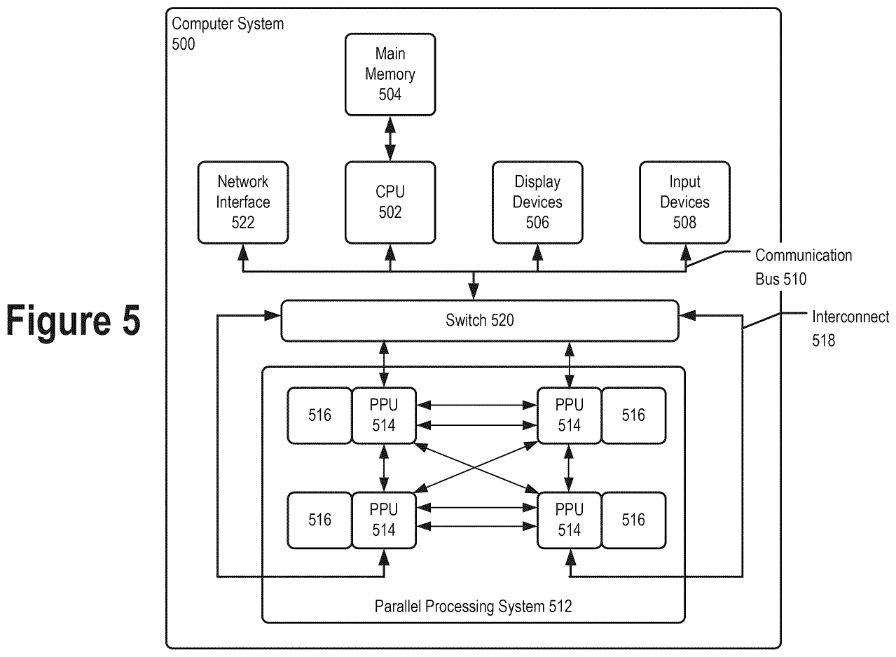

FIG. 5 illustrates a computer system 500, according to at least one embodiment. In at least one embodiment, computer system 500 is configured to implement various processes and methods described throughout this disclosure.

In at least one embodiment, computer system 500 comprises, without limitation, at least one central processing unit (“CPU”) 502 that is connected to a communication bus 510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 500 includes, without limitation, a main memory 504 and control logic (e.g., implemented as hardware, software, or a combination thereof) and data are stored in main memory 504 which may take form of random access memory (“RAM”). In at least one embodiment, a network interface subsystem (“network interface”) 522 provides an interface to other computing devices and networks for receiving data from and transmitting data to other systems from computer system 500.

In at least one embodiment, computer system 500, in at least one embodiment, includes, without limitation, input devices 508, parallel processing system 512, and display devices 506 which can be implemented using a conventional cathode ray tube (“CRT”), liquid crystal display (“LCD”), light emitting diode (“LED”), plasma display, or other suitable display technologies. In at least one embodiment, user input is received from input devices 508 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 504 and/or secondary storage. Computer programs, if executed by one or more processors, enable system 500 to perform various functions in accordance with at least one embodiment. memory 504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 502; parallel processing system 512; an integrated circuit capable of at least a portion of capabilities of both CPU 502; parallel processing system 512; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 500 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 512 includes, without limitation, a plurality of parallel processing units (“PPUs”) 514 and associated memories 516. In at least one embodiment, PPUs 514 are connected to a host processor or other peripheral devices via an interconnect 518 and a switch 520 or multiplexer. In at least one embodiment, parallel processing system 512 distributes computational tasks across PPUs 514 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 514, although such shared memory may incur performance penalties relative to use of local memory and registers resident to a PPU 514. In at least one embodiment, operation of PPUs 514 is synchronized through use of a command such as_syncthreads ( ), wherein all threads in a block (e.g., executed across multiple PPUs 514) to reach a certain point of execution of code before proceeding.

The switches within each layer (e.g., edge layer, aggregation layer, core layer) may be 1U switches, where “IU” refers to the industry-standard size for rack-mounted switches and servers. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

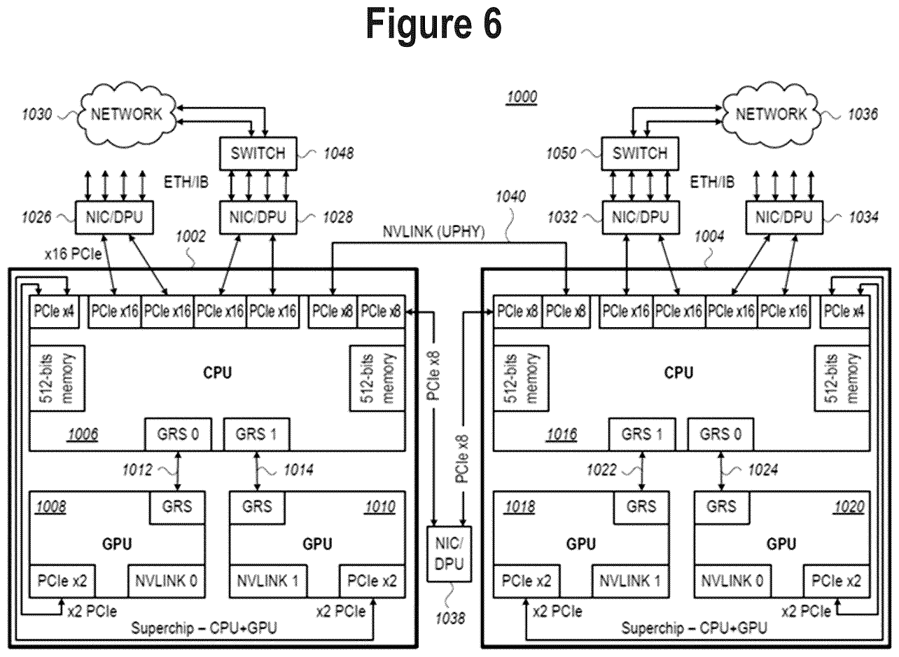

FIG. 6 is a block diagram that schematically illustrates a computing system 1000, e.g., a data center or a High-Performance Computing (HPC) cluster, in accordance with an embodiment that is described herein. System 1000 comprises a plurality of subsystems, e.g. multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 6 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 6, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 6, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communication with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 6 may comprise, for example, Nvidia Quantum-2 switches. The NICs/DPUs in the figure may comprise, for example, Nvidia Bluefield DPUs.

In various embodiments, any of the network devices of system 1000, e.g., any of NICs/DPUs 1026, 1028, 1032, 1034, and 1038, and/or any of switches 1048 and 1050, may include electrical components in accordance with various embodiments.

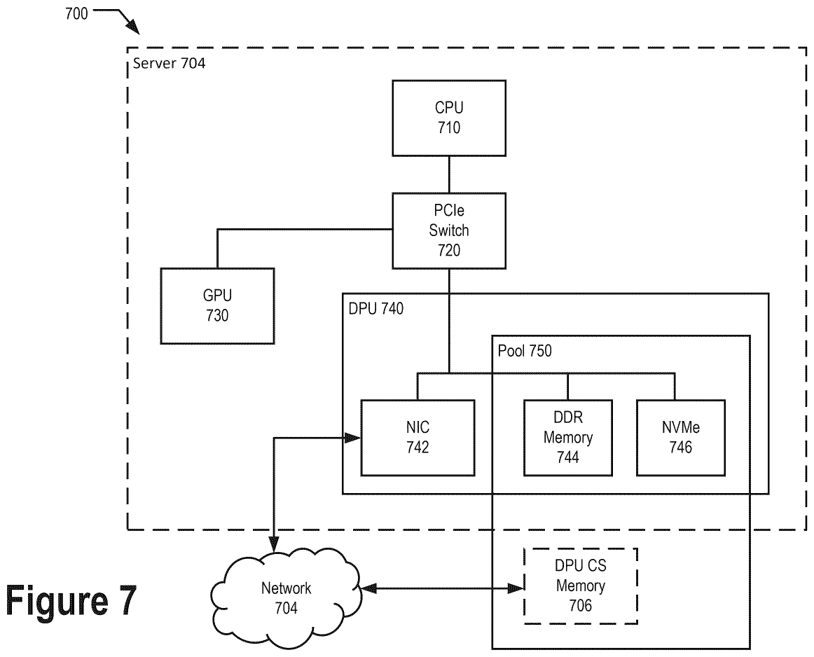

FIG. 7 illustrates an example computing environment 700 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 700 may include a server 702 which may be used to perform HPC workloads, such as AI training or machine learning model training. In an embodiment, the server 702 may be an application instance or a compute node. The server 702 may include a CPU 710 associated with a switch 720, such as a peripheral component interconnect express (PCIe) switch, which may control at least some data transmission over communication paths interconnecting various components. In an embodiment, the CPU 710 may include a root complex processor.

The PCIe switch 720 may also be associated with a GPU 730 and a DPU 740, and may transmit data between at least some of the CPU 710, the GPU 730, the DPU 740, and other components. In an embodiment, the PCIe switch 720 may be associated with more than one GPU or more than one DPU. In another embodiment, the PCIe switch 720 may be located within the DPU 740. The PCIe switch 720 may manage the transfer of at least some data between the CPU 710, the GPU 730, and the DPU 740. In another embodiment, the number of GPUs associated with the PCIe switch 720 may be equal to the number of DPUs associated with the PCIe switch 720. In at least one embodiment, the server 702 may include, without limitation, any number of the CPUs 710, the PCIe switches 720, the GPUs 730, and/or the DPUs 740, in any combination. For example, in at least one embodiment, server 702 could include eight, sixteen, thirty-two, and/or more GPUs 730. In at least one embodiment, communication paths interconnecting various components, including but not limited to the CPU 710, the PCIe switch 720, the GPU 730, and the DPU 740, in FIG. 7 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 740 may include a network interface controller (NIC) 742, a DDR memory 744, and a non-volatile memory express (NVMe) device 746. The NIC 742 may be able to interface with a network 704, which may also interface with additional NVMe devices available to the DPU 740, such as over fabric. In an embodiment, the DPU 740 may not include the NVMe device 746. In another embodiment, the NVMe device 746 may be located on the server 702 and not on the DPU 740. In yet another embodiment, the computing environment 700 may include more than one of the NVMe device 746, such as a first NVMe device in the DPU 740 and a second first NVMe device on the server 702 an associated directly with the PCIe switch 720. In an embodiment, the DPU 740 may not include the DDR memory 744 and may include a computational storage services (CSS) in place of, or in addition to, the DDR memory 744. For example, computing environment 700 may include DPU computational storage (CS) memory 706 available to the DPU 740 as part of the CSS. The network 704 may be able to interface with the DPU CS memory 706 through the NIC 742, according to any suitable interface protocol, such as remote direct memory access (RDMA) over Ethernet, InfiniBand, Fiber Channel, etc.

The total memory of the computing environment 700 available for data storage may be expanded through the use of the DPU 740 on nodes of the system. The DPU 740 may have access to a pool 750 of memory already available to the server 702, such as double data rate (DDR) memory, on-board NVMe devices, NVMe devices over fabric, and CS. The pool 750 of memory may include at least one of the DDR memory 744, NVMe 746, and the DPU CS memory 706. The DPU 740 may also be able to access the available memory of other DPUs as part of the pool 750, and other DPUs may be able to access the available memory of DPU 740, such as the pool 750. This available memory can be accessed and utilized for data storage, without the addition of compute resources, such as compute nodes, which would be required using other solutions. The available pool 750 accessible to the DPU 740 may be provisioned for the server 702 to expand the total memory available for data storage, such as to reduce the data storage load on the CPU 710 or the GPU 730, which can instead increase the utilization of their memory for processing. For example, during training of an AI, the model states, residual states, activation functions, and checkpoints can be stored, or offloaded, on the pool 750 accessible to the DPU 740.

In the above description, an embodiment is an example or implementation of the disclosure. The various appearances of “one embodiment,” “an embodiment,” “certain embodiments,” or “some embodiments” do not necessarily all refer to the same embodiments. Although various features of the disclosure may be described in the context of a single embodiment, the features may also be provided separately or in any suitable combination. Conversely, although the disclosure may be described herein in the context of separate embodiments for clarity, the disclosure may also be implemented in a single embodiment. Certain embodiments of the disclosure may include features from different embodiments disclosed above, and certain embodiments may incorporate elements from other embodiments disclosed above. The disclosure of elements of the disclosure in the context of a specific embodiment is not to be taken as limiting their use in the specific embodiment alone. Furthermore, it is to be understood that the disclosure can be carried out or practiced in various ways and that the disclosure can be implemented in certain embodiments other than the ones outlined in the description above.

The disclosure is not limited to those diagrams or to the corresponding descriptions. For example, flow need not move through each illustrated box or state, or in exactly the same order as illustrated and described. Meanings of technical and scientific terms used herein are to be commonly understood as by one of ordinary skill in the art to which the disclosure belongs, unless otherwise defined. While the disclosure has been described with respect to a limited number of embodiments, these should not be construed as limitations on the scope of the disclosure, but rather as exemplifications of some of the preferred embodiments. Other possible variations, modifications, and applications are also within the scope of the disclosure. Accordingly, the scope of the disclosure should not be limited by what has thus far been described, but by the appended claims and their legal equivalents.

What is claimed is:

1. An electrical component comprising:
at least one conducting trace configured for conducting radiofrequency (RF) signals, the at least one conducting trace having a broadband conductive material applied onto one or more specific locations along the at least one conducting trace.

2. The electrical component of claim 1, further comprising a substrate, wherein at least a portion of the at least one conducting trace is disposed on the substrate.

3. The electrical component of claim 1, wherein the broadband conductive material is configured to improve a signal integrity of the RF signals transmitted along the at least one conducting trace compared to if the broadband conductive material was not present.

4. The electrical component of claim 1, wherein each specific location of the one or more specific locations is defined by at least one of:
(a) a detected surface roughness of the at least one conducting trace at the specific location,
(b) a change in direction of the at least one conducting trace with respect to design and/or lithographic parameters at the specific location, or
(c) a change in direction of the at least one conducting trace on a substrate hosting the at least one conducting trace at the specific location.

5. The electrical component of claim 1, wherein the broadband conductive material comprises graphene.

6. The electrical component of claim 1, wherein the one or more specific locations constitute less than 10% of a surface area of the at least one conducting trace.

7. The electrical component of claim 1, wherein the electrical component is at least one of a semiconductor device, a printed circuit board, or an integrated circuit package.

8. A method for fabricating an electrical component, the method comprising:
applying a broadband conductive material to one or more specific locations along a conducting trace, wherein each specific location of the one or more specific locations was identified based at least in part on an anticipated or detected surface roughness of the specific location.

9. The method of claim 8, further comprising:
defining the specific location along the conducting trace based at least in part on the anticipated or detected surface roughness at the specific location.

10. The method of claim 9, wherein the defining of the specific location comprises inspecting the conducting trace for surface roughness and detecting specific locations along the conducting trace having surface roughness that satisfies an action threshold.

11. The method of claim 9, wherein the defining of the specific location comprises identifying a location corresponding to a change in direction of the conducting trace with respect to design and/or lithographic parameters.

12. The method of claim 9, wherein the defining of the specific location comprises inspecting the conducting trace to detect changes in direction of the conducting trace on a substrate hosting the conducting trace.

13. The method of claim 8, wherein applying the broadband conductive material onto the one or more specific locations along the conducting trace comprises:
patterning a mask on a substrate hosting the conducting trace such that unmasked regions are formed at the one or more specific locations and masked regions are formed on portions of the substrate that are not the one or more specific locations, and
depositing the broadband conductive material onto the unmasked regions that correspond to the one or more specific locations.

14. The method of claim 13, further comprising removing the mask while leaving the broadband conductive material on the one or more specific locations.

15. The method of claim 8, wherein the broadband conductive material comprises graphene.

16. The method of claim 8, wherein the one or more specific locations constitute less than 10% of a surface area of the conducting trace.

17. The method of claim 8, further comprising:
prior to applying the broadband conductive material to the one or more specific locations, determining a signal integrity (SI) of the conducting trace; and
after applying the broadband conductive material to the one or more specific locations, verifying an improvement of the SI of the conducting trace following application of the broadband conductive material.

18. The method of claim 17, further comprising:
identifying one or more locations with persisting SI reduction based on the verifying of the improvement of the SI of the conducting trace; and
reiterating application of the broadband conductive material at the one or more locations with the persisting SI reduction.

19. A circuit formed at least in part on a substrate, the circuit comprising:
a conducting trace that has a broadband conductive material applied onto one or more specific locations along the conducting trace.

20. The circuit of claim 19, wherein the one or more specific locations correspond to areas of expected or detected surface roughness of the conducting trace and the one or more specific locations constitute less than 10% of a surface area of the conducting trace.
